(19) United States
(12) Patent Application Publication
(10) Pub. No.: US 2021/0255010 A1
(43) Pub. Date: Aug. 19, 2021

(54) METROLOGY AND AUTOMATION FIELD DEVICE

(71) Applicant: Endress+Hauser Flowtec AG, Reinach (CH)

(72) Inventors: Lukas Tanner, Oberwil BL (CH); Mihai Vitanescu, Rombach (CH); Timo Kretzler, Binzen (DE)

(21) Appl. No.: 16/972,974

(22) PCT Filed: May 10, 2019
(86) PCT No.: PCT/EP2019/062091

§ 371 Date: Dec. 7, 2020

(30) Foreign Application Priority Data
Jun. 8, 2018 (DE) 10 2018 113 723.0

(51) Int. Cl. G01F 1/60; G06F 3/14

(52) U.S. Cl. CPC G01F 1/60; G06F 3/1446

(57) ABSTRACT

The invention relates to a field device of measurement- and automation technology, comprising: a measuring transducer which is adapted to register at least one measured variable and, at any one time, to output at least a first measured value representing the measured variable; a display unit which is adapted to display measuring- and/or operating parameters; and an electronic measuring/operating circuit which is adapted to operate the measuring transducer and/or the display unit, as well as to calculate from the first measured value a derived, second measured value. The display unit has a screen that has a first region with a first display technology and a second region with a second display technology. The first region is embodied reflectively or transreflectively and the second region is embodied transmissively.

The invention relates to a display unit equipped, field device of measurement- and automation technology.

The display unit of a field device is often used to display information concerning measured variables or concerning a measured process. An example is disclosed in DE102016106179A1.

Depending on applied display technology, such display units operate either in a low electrical power mode limited to a rudimentary information display, or in a high electrical power mode, in which case they can then show information in a more flexible manner. In the fields of metrology and automation, low electrical power requirement and a high quality information display are very important.

An object of the invention is, consequently, to provide a display unit, which operates with low electrical power and provides a high quality information display.

The object is achieved by a field device as defined in independent claim 1.

A field device of the invention for measurement- and automation technology comprises:

A measuring transducer, which is adapted to register at least one measured variable and, at any one time, to output at least a first measured value representing the measured variable;

a display unit, which is adapted to display measuring- and/or operating parameters;

an electronic measuring/operating circuit, which is adapted to operate the measuring transducer and/or the display unit, as well as to calculate from the first measured value a derived, second measured value;

wherein the display unit has a screen,

wherein the screen has a first region with a first display technology and a second region with a second display technology,

wherein the first region is embodied reflectively or transreflectively and wherein the second region is embodied transmissively.

In an embodiment, the first region is adapted to be operated steadily, and the second region is adapted, when required, to be activated by event control.

In this way, a low power display of information can, if necessary, be combined with a high quality, for example, colored and/or highly resolved, information display.

In an embodiment, the first region is, at least sectionally, contact sensitive or a contact sensitivity of the first region is, at least sectionally, activatable.

In an embodiment, the field device includes an energy storer, which is adapted to supply the field device with energy, wherein the field device has an energy supply connection, by means of which an external energy supply is connectable,

wherein the second region is adapted to be activated upon connection of an external energy supply.

In an embodiment, the second region is adapted to display at least one element of the following list:

at least one measured value,

at least one operating parameter,

at least one time dependence of at least one measured value and/or at least one operating parameter,

a processed time dependence of the previous element,

a selection menu for selecting information to be displayed.

The list is to be construed as by way of example, and not as limiting, or complete.

In an embodiment, the first region has at least two operating modes, wherein the first region is adapted to work in a first operating mode in the case of non-activated second region and in a second operating mode in the case of activated second region.

In this way, the behavior of the first region can be matched to the state of the second region.

In an embodiment, the first operating mode includes display of at least one operating parameter and/or at least one measured value, wherein the second operating mode comprises provision of at least one contact sensitive section.

Additionally, in the first operating mode also at least one contact sensitive section can be adapted to change between different information to be displayed, such as, for example, measured values.

In an embodiment, the second operating mode comprises provision of a plurality of contact sensitive sections, wherein at least one section displays an operating key or a jump function or a scrollbar or is part of a scrollbar.

The at least one operating key can be adapted, for example, for navigating through an operating- or selection menu displayed in the second region. A jump function is adapted, for example, to jump directly to a frequently required information display.

In an embodiment, the first display technology is a single color display technology and is based, for example, on a liquid crystal technology. In this way, an energy saving operation of the display in the first operating mode can be assured.

In an embodiment, the second display technology is a multicolor display technology, wherein the second display technology is, for example, based on one of the following principles:

TFT, OLED.

In this way, for example, in the case an external energy supply, a high quality information display can be selected.

In an embodiment, the second region is, at least sectionally, contact sensitive or a contact sensitivity of the second region is, at least sectionally, activatable.

In an embodiment, the first region operates at a power of less than 10 mW and preferably less than 3 mW and, especially, less than 1 mW, and/or wherein the second region operates at a power of less than 1000 mW and preferably less than 500 mW and, especially, less than 300 mW.

In an embodiment, the first region has in a breadth and/or in a height at least 50 pixels and preferably at least 100 pixels and preferably at least 200 pixels, and

wherein the second region has in a breadth and/or in a height at least 150 pixels and preferably at least 250 pixels and preferably at least 350 pixels.

In an embodiment, the screen has in a breadth and/or height an expanse of at most 12 cm and, especially, at most 8 cm and preferably at most 6 cm.

In an embodiment, the field device is a field device of flow measurement technology and has at least one measuring tube for conveying a medium.

In an embodiment, the field device is a magnetically inductive flow measuring device,

wherein the measuring transducer comprises:

a magnet system for producing a magnetic field extending perpendicularly to a measuring tube axis,

at least one pair of measuring electrodes for sensing a flow dependent voltage induced in the medium.

Especially in the case of magnetically inductive flow measuring devices, in the case of which the magnet system already operates at an elevated power, a display unit of the invention is advantageous, since, then, the energy storer is less greatly burdened and the operating time of the magnetically inductive flow measuring device can be lengthened.

The invention will now be described based on examples of embodiments presented in the appended drawing, the figures of which show as follows:

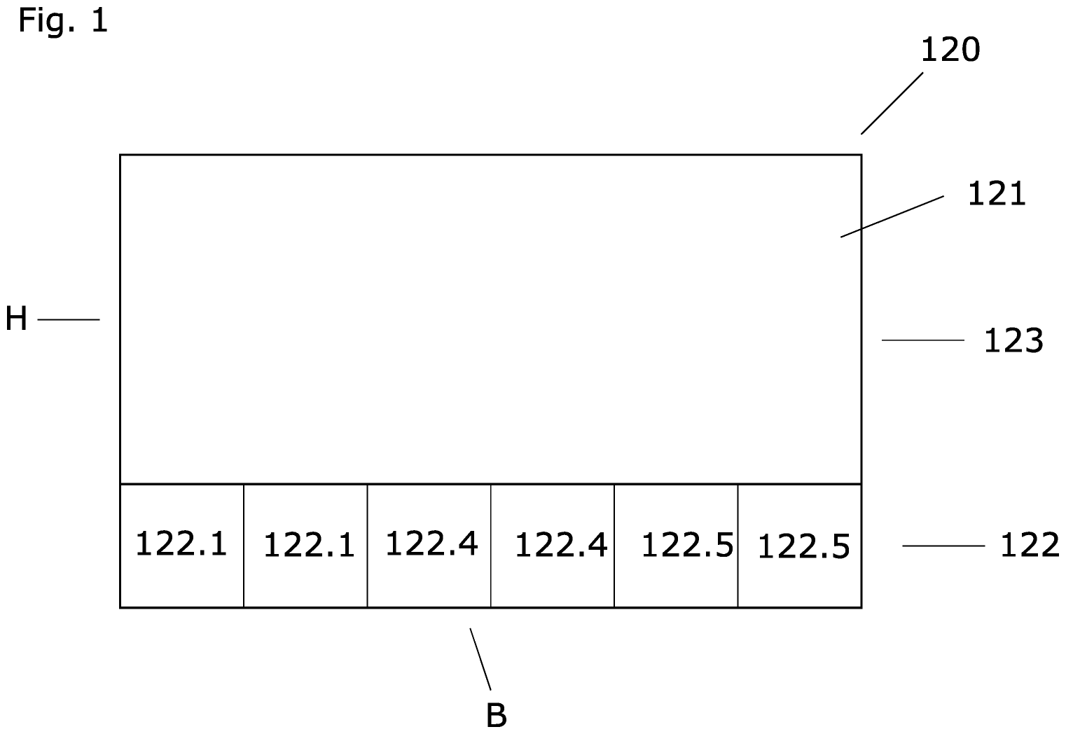

FIG. 1 by way of example, in a first operating mode, a display unit of the invention for a field device of the invention.

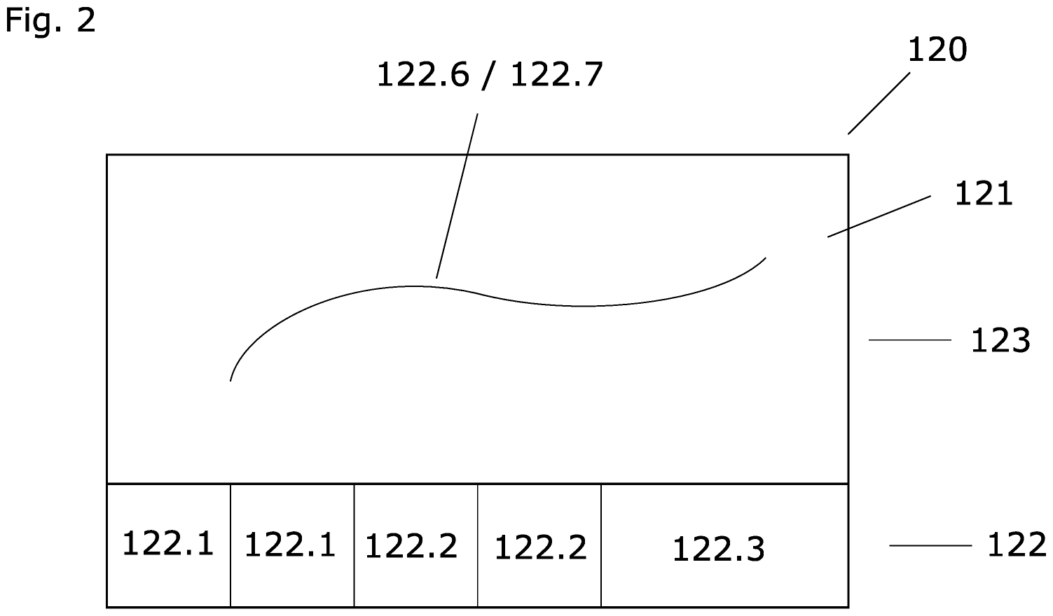

FIG. 2 the display unit of FIG. 1 in a second operating mode.

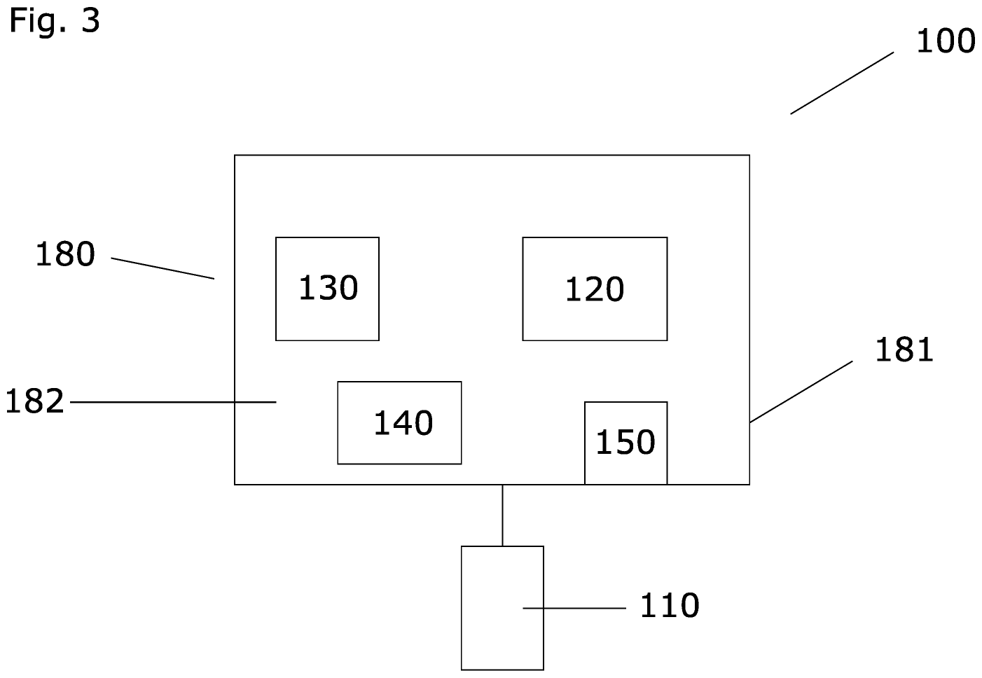

FIG. 3 by way of example, a field device of the invention.

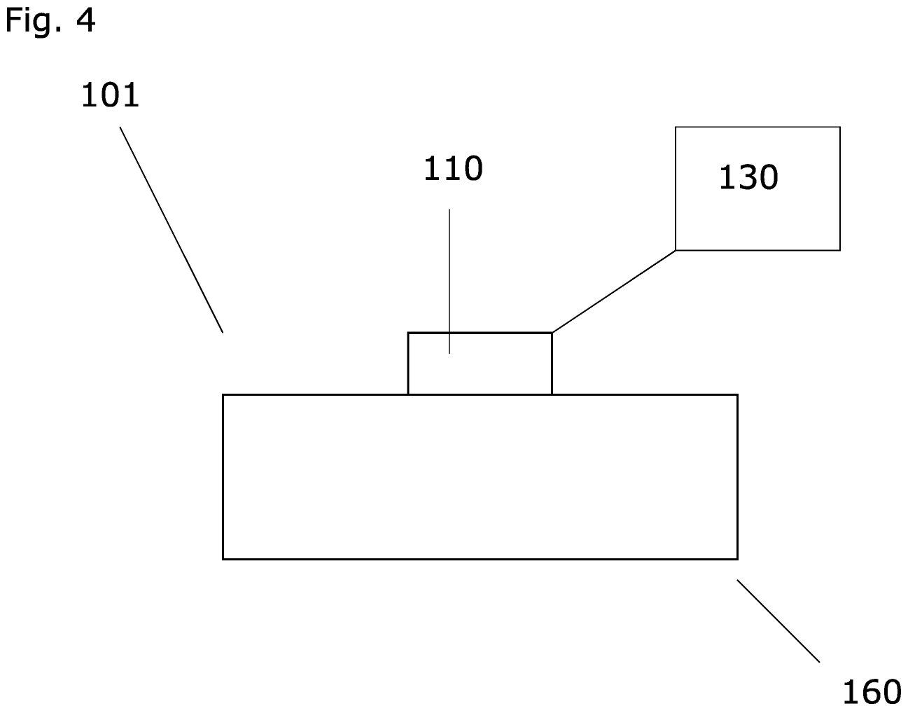

FIG. 4 by way of example, a field device of the invention.

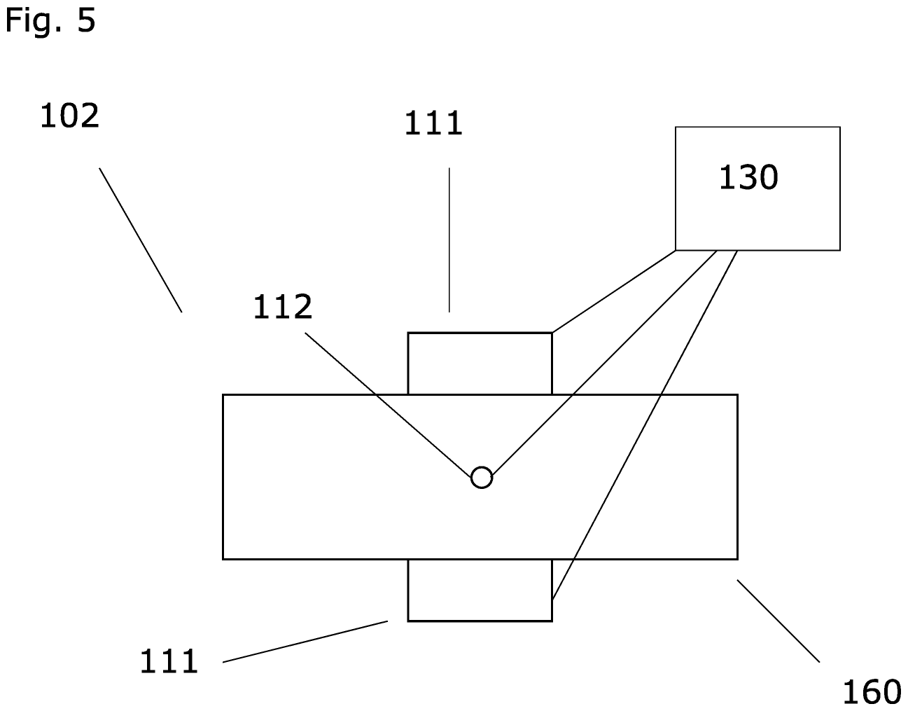

FIG. 5 by way of example, a field device of the invention.

FIG. 1 shows, by way of example, a display unit 120 of the invention in a first operating mode, wherein the display unit has a screen 121 with a first region 122 and a second region 123. The first region 122 uses, in such case, a first energy-saving display technology, such as, for example, a liquid crystal technology, and the second region 123 uses a second display technology, which has a higher power requirement and can, for example, display contents with multiple colors and/or highly resolved. The second region is turned off in the first operating mode of the display unit, and turned on in a second operating mode, wherein the turning on of the second region can be according to need, i.e. event-controlled. Thus, the second region can, for example, be turned on upon the connecting of an external energy supply to the field device.

In the first operating mode, the first region can, for example, be adapted, such as shown, to display operating buttons 122.1, measured values 122.4 and operating parameters 122.5, wherein at least in the region of the operating buttons a contact sensitivity is provided. The illustrated embodiment is purely by way of example and is not to be construed as limiting.

The screen 121 has a breadth B and/or height H of at most 12 cm and, especially, at most 8 cm, in order that the display unit can be embodied compactly.

The first region 122 has in a first breadth and/or in a first height at least 50 pixels and preferably at least 100 pixels and preferably at least 200 pixels, and wherein the second region has in a second breadth and/or in a second height at least 150 pixels and preferably at least 250 pixels and preferably at least 350 pixels. Thus, by means of the higher pixel count of the second region, information can be displayed with more detail.

The geometric embodiment of the screen as well as of the first region and the second region, such as shown in FIG. 1, is, by way of example, and is not to be construed as limiting.

FIG. 2 shows the display unit in the second operating mode with second region 123 turned on. Displayed in the second region is a time dependence 122.6, or an upgraded time dependence 122.7, of a measured variable or an operating mode. An upgrading of a curve can involve, for example, a smoothing or filtering or a general signal processing. Instead of a curve, also other items can be displayed, such as, for example, operating instructions, settable parameters, at least one menu structure, at least one graph, such as, for example, a bar chart. Such graphs are, for example, of limit values or historical minimum- or maximum values of, for example, measured values. These enumerations are not to be construed as limiting.

As indicated, in the second operating mode, such as shown, the first region can have, for example, a different layout than in the first operating mode. For example, the first region can now have operating buttons 122.1, jump functions 122.2 and at least one scrollbar 122.3. Also in this case, the shown layout of the first region is by way of example,

FIG. 3 shows, by way of example, a generalized field device 100 of the invention having a housing 180 with a housing wall 181, which surrounds a housing chamber 182. The field device includes a measuring transducer 110, by means of which a measured variable is registrable and, at any one time, at least a first measured value representing the measured variable can be output. Such a measuring transducer can comprise, for example, at least one ultrasonic transducer, at least one thermometer or other sensors based on other physical principles. The field device includes, furthermore, an energy storer 140 for energy supply, an energy supply connection 150 for connecting an external energy source and an electronic measuring/operating circuit 130 for operating the field device. The display unit 120 can, such as shown in FIG. 3, be set in the housing wall. Alternatively, the display unit can also be secured on an outer side of the housing wall or be spaced from the housing. Communication between display unit and electronic operating circuit 130 can occur by means of an electrical connection or per radio. The electronic measuring/operating circuit 130 is connected by means of electrical connections with the measuring transducer 110, the energy storer 140 as well as energy supply connection 150.

FIG. 4 shows a flow measuring device for measuring a mass flow or a flow velocity of a medium flowing through a measuring tube, comprising the measuring tube 160, a measuring transducer 110 arranged on the measuring tube, and an electronic measuring/operating circuit 130. Other elements shown in FIG. 3 are, for reasons of perspicuity, not shown. Depending on measuring principle, the measuring transducer can also be arranged partially or completely in the measuring tube.

FIG. 5 shows a magnetically inductive flow measuring device comprising a measuring tube 160, a measuring transducer comprising a magnet system 111, a pair of measuring electrodes 112 (due to the viewing direction, only one measuring electrode is shown) and an electronic measuring/operating circuit 130. Other elements shown in FIG. 3 are, for reasons of perspicuity, not shown. The magnet system is adapted to produce a magnetic field extending perpendicularly to a measuring tube axis. By means of the measuring electrodes 112, a flow dependent electrical voltage produced by the magnetic field and the flow of the medium can be registered and taken into consideration for deriving measured values of flow.

### LIST OF REFERENCE CHARACTERS

100 field device
101 flow measuring device
102 magnetically inductive flow measuring device
110 measuring transducer
111 magnet system
112 measuring electrode
120 display unit
121 screen
122 first region
122.1 operating key
122.2 jump function
122.3 scrollbar
122.4 measured value
122.5 operating parameters
122.6 time dependence
122.7 upgraded time dependence
123 second region
130 electronic measuring/operating circuit
140 energy storer
150 energy supply connection
160 measuring tube
180 housing
181 housing wall
182 housing chamber
B breadth
H height

1-15. (canceled)

16. A field device of measurement- and automation technology, comprising:
a measuring transducer adapted to register at least one measured variable and, at any one time, to output at least a first measured value representing the measured variable;
a display unit adapted to display measuring- and/or operating parameters; and
an electronic measuring/operating circuit adapted to operate the measuring transducer and/or the display unit, as well as to calculate from the first measured value a derived, second measured value,
wherein the field device includes a housing having a housing wall and a housing chamber formed by the housing wall, in which housing at least the measuring/operating circuit is arranged,
wherein the display unit has a screen having a first region with a first display technology and having a second region with a second display technology, and
wherein the first region is embodied reflectively or transreflectively and the second region is embodied transmissively.

17. The field device as claimed in claim 16,
wherein the first region is adapted to be operated steadily, and wherein the second region is adapted to be activated by event control when required.

18. The field device as claimed in claim 16,
wherein the first region is, at least sectionally, contact sensitive or a contact sensitivity of the first region is, at least sectionally, activatable.

19. The field device as claimed in claim 16, further comprising:
an energy storer adapted to supply the field device with energy; and
an energy supply connection by which an external energy supply is connectable,
wherein the second region is adapted to be activated upon connection of an external energy supply.

20. The field device as claimed in claim 16,
wherein the second region is adapted to display at least one element of the following list:
at least one measured value,
at least one operating parameter,
at least one time-dependence of at least one measured value and/or at least one operating parameter, and
a processed time dependence of the previous element.

21. The field device as claimed in claim 17,
wherein the first region has at least two operating modes, wherein the first region is adapted to work in a first operating mode in the case of non-activated second region and in a second operating mode in the case of activated second region.

22. The field device as claimed in claim 21,
wherein the first operating mode includes display of at least one operating parameter and/or at least one measured value and the second operating mode comprises provision of at least one contact sensitive section.

23. The field device as claimed in claim 22,
wherein the second operating mode includes a provision of a plurality of contact sensitive sections, and
wherein at least one section of the plurality of contact sensitive sections displays an operating key or a jump function or a scrollbar or is part of a scrollbar.

24. The field device as claimed in claim 16,
wherein the first display technology is a single color display technology.

25. The field device as claimed in claim 24,
wherein the second display technology is a multicolor display technology and is based on one of the following principles:
TFT, OLED.

26. The field device as claimed in claim 22,
wherein the second region is, at least sectionally, contact sensitive or a contact sensitivity of the second region is, at least sectionally, activatable.

27. The field device as claimed in claim 16,
wherein the first region operates at a power of less than 10 mW, and/or wherein the second region operates at a power of less than 1000 mW.

28. The field device as claimed in claim 16,
wherein the first region has in a first breadth and/or in a first height at least 50 pixels, and
wherein the second region has in a second breadth and/or in a second height at least 150 pixels.

29. The field device as claimed in claim 16,
wherein the screen has in a breadth and/or height an expanse of at most 12 cm.

30. The field device as claimed in claim 16,
wherein the field device is a flow measuring device and has at least one measuring tube for conveying a medium,
wherein the field device is a magnetically inductive flow measuring device and its measuring transducer includes:
a magnet system for producing a magnetic field extending perpendicularly to a measuring tube axis, and
at least one pair of measuring electrodes for sensing a flow dependent voltage induced in the medium by the magnetic field.
